(19) United States
(12) Patent Application Publication
(10) Pub. No.: US 2010/0147382 A1
(43) Pub. Date: Jun. 17, 2010

(54) PORTABLE SOLAR POWER GENERATOR WITH INTERNAL LIGHT GUIDE ELEMENT

(75) Inventors: KUO-FENG CHIANG, Chu-Nan (TW); PING-YU CHEN, Chu-Nan (TW); NAI-WEN ZHANG, Chu-Nan (TW); SHAN-JU LIN, Chu-Nan (TW)

Correspondence Address: PCE INDUSTRY, INC.;ATT. Steven Reiss, 288 SOUTH MAYO AVENUE, CITY OF INDUSTRY, CA, 91789, US

(73) Assignee: FOXSEMICON INTEGRATED TECHNOLOGY, INC., Chu-Nan (TW)

(21) Appl. No.: 12/615,249

(22) Filed: Nov. 9, 2009

(30) Foreign Application Priority Data
Dec. 15, 2008 (CN) 200810306258.9

(51) Int. Cl. H01L 31/00

(52) U.S. Cl. 136/259

(57) ABSTRACT

An exemplary portable solar power generator includes a hollow light pervious housing, a light guide element, a condensing lens, a solar cell unit, and a connector assembly. The housing has a first refractive index, and sunlight enters the housing by passing through an outer surface thereof. The light guide element is positioned in and attached to the housing, which has a second refractive index larger than the first refractive index. The condensing lens is positioned in the housing, which is configured for converging the light incident thereon. The solar cell unit is positioned in the light pervious housing and located at a side of the condensing lens opposite to the light guide element. The solar cell unit is configured for receiving the light converged by the condensing lens and converting the received sunlight into electrical energy. The connector assembly is electrically coupled to the solar cell unit.

### BACKGROUND

1. Technical Field

The present disclosure relates to solar cell technology, and in particular, relates to portable solar power generators.

2. Description of Related Art

Currently, portable electronic devices such as personal digital assistants (PDAs), mobile phones, MP3 players and the like are very popular due to their versatile and enjoyable functions. However, more functions also mean higher power consumption rates, and currently available batteries cannot always conveniently meet the increased energy supply requirements of these devices. Thus, many of these portable electronic devices suffer from an unduly limited service time, after which their batteries need to be replaced or recharged. However, in many or most outdoor conditions, a power supply or a power outlet may not be available for recharging the batteries.

Therefore, there is a desire to provide a portable power generator for supplying electrical energy for portable electronic devices.

### BRIEF DESCRIPTION OF THE DRAWINGS

Many aspects of the disclosure can be better understood with reference to the following drawings. The components in the drawings are not necessarily drawn to scale, the emphasis instead being placed upon clearly illustrating the principles of the disclosure. Moreover, in the drawings, like reference numerals designate corresponding parts throughout the different views.

FIG. 1 is an isometric view of a portable solar power generator including a solar cell unit in accordance with a first exemplary embodiment.

FIG. 2 is a cross-sectional view of part of the portable solar power generator of FIG. 1, taken along line II-II thereof.

FIG. 3 is an isometric view of a portable solar power generator in accordance with a second exemplary embodiment.

FIG. 4 is a cross-sectional view of part of the portable solar power generator of FIG. 3, taken along line IV-IV thereof.

FIG. 5 is a cross-sectional view of part of a portable solar power generator in accordance with a third exemplary embodiment.

FIG. 6 is an isometric view of a portable solar power generator in accordance with a fourth exemplary embodiment.

FIG. 7 is a cross-sectional view of part of the portable solar power generator of FIG. 6, taken along line VII-VII thereof.

### DETAILED DESCRIPTION

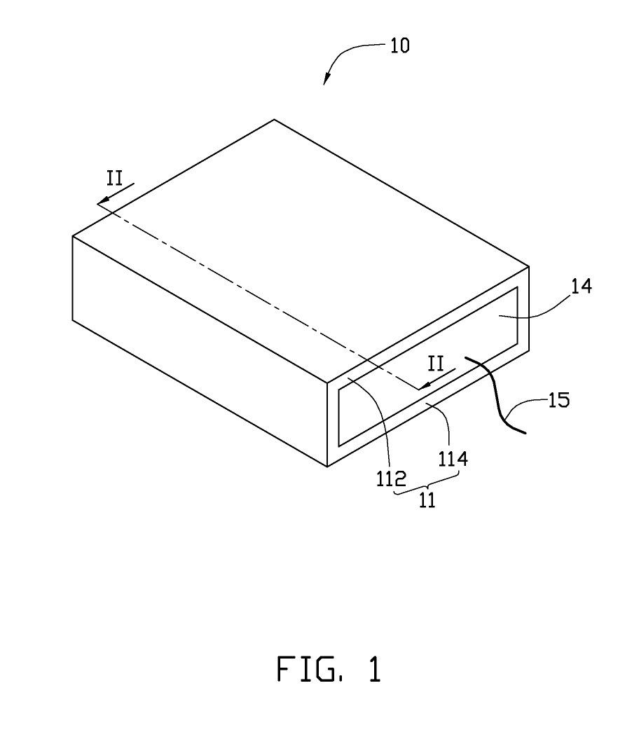

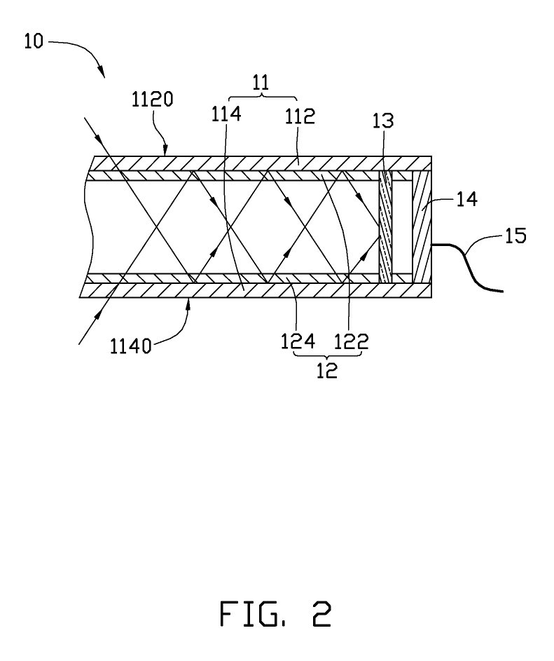

As illustrated in FIGS. 1 and 2, a portable solar power generator 10 provided in a first exemplary embodiment includes a light pervious housing 11, a light guide element 12, a condensing lens 13, a solar cell unit 14, and a connector assembly 15.

The light pervious housing 11 has a hollow plate-shaped structure, and includes a top plate 112 and a bottom plate 114. A top surface 1120 of the top plate 112 serves as a first light incident surface of the light pervious housing 11, and a bottom surface 1140 of the bottom plate 114 serves as a second light incident surface of the light pervious housing 11. Sunlight passes through the top surface 1120 of the top plate 112 and the bottom surface 1140 of the bottom plate 114 to enter the light pervious housing 11. The top plate 112 and a bottom plate 114 both have a first refractive index.

The light guide element 12 is positioned between the top plate 112 and the bottom plate 114. The light guide element 12 includes a first reflecting plate 122 and an opposite second reflecting plate 124. The first reflecting plate 122 and the second reflecting plate 124 are respectively in contact with the top plate 112 and the bottom plate 114. The first reflecting plate 122 and the second reflecting plate 124 both have a second refractive index, which is greater than the first refractive index. In one example, the first refractive index can be 1.4, and the second refractive index can be 1.6.

The condensing lens 13 is positioned in the light pervious housing 11, near the solar cell unit 14. The condensing lens 13 may be positioned adjacent the light guide element 12, or in the light guide element 12. In the illustrated embodiment, the condensing lens 13 is positioned in the light guide element 12. In particular, two opposite ends of the condensing lens 13 are embedded in end portions of the first and second reflecting plates 122, 124, respectively. The condensing lens 13 converges light incident thereon.

The solar cell unit 14 is positioned in the light pervious housing 11 adjacent the light guide element 12, and near the condensing lens 13. That is, the solar cell unit 14 is located at a side of the condensing lens 13 opposite to the side where the majority of the light guide element 12 is located. The solar cell unit 14 is configured for receiving the light converged by the condensing lens 13, and converting the received light into electrical energy.

The connector assembly 15 is electrically coupled to the solar cell unit 14. A power consuming device (i.e., an energy storing means, not shown) can be connected to an outer end of the connector assembly 15. Thus, the electrical energy generated from the solar cell unit 14 can be transferred to the power consuming device by the connector assembly 15.

Due to the first refractive index being less than the second refractive index, sunlight can successfully enter the light guide element 12 by passing through the top plate 112 and the first reflecting plate 122 and by passing through the bottom plate 114 and the second reflecting plate 122. Such light between the first reflecting plate 122 and the second reflecting plate 124 can then be trapped in the housing 11 by total internal reflection (TIR). Thereby, the sunlight received in the light guide element 12 can efficiently transmit to the condensing lens 13. The light introduced onto the condensing lens 13 can then be converged onto the solar cell unit 14, and the solar cell unit 14 can convert the received light into electrical energy. The electrical energy may be stored in the solar cell unit 14. The electrical energy generated from the solar cell unit 14 can be transferred to the power consuming device (not shown) by the connector assembly 15. In addition, because of the convergence of the light by the condensing lens 13, the light introduced onto the solar cell unit 14 is centralized. Accordingly, a photoelectric conversion efficiency of the solar cell unit 14 is improved.

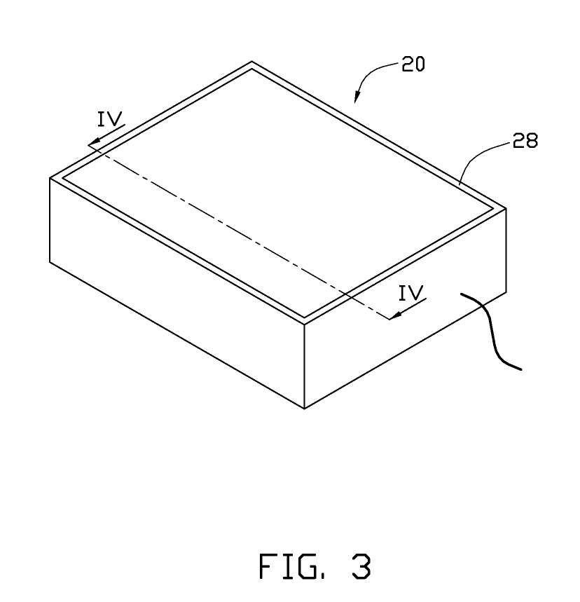

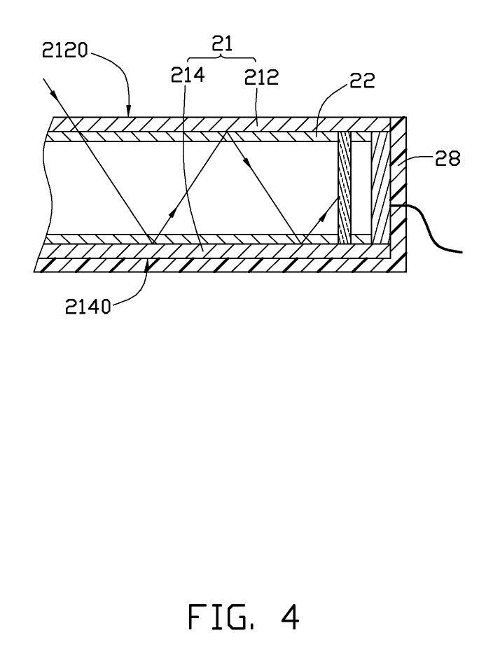

Referring to FIGS. 3 and 4, a portable solar power generator 20 provided in a second exemplary embodiment is similar to the portable solar power generator 10 of the first embodiment, except that the portable solar power generator 20 further includes a protection layer 28.

The protection layer 28 is arranged on most or all of outside surfaces of a light pervious house 21. In the illustrated embodiment, the protection layer 28 is arranged on most of the outside surfaces of the light pervious house 21, including on a bottom surface 2140 of a bottom plate 214 of the light pervious house 21. The protection layer 28 is for avoiding damage to the portable solar power generator 20 due to impact, dampness, strong light, and other hazards. A material of the protection layer 28 may be selected from silicone, plastics, and other suitable light pervious materials. Alternatively, the protection layer 28 may be made of opaque material. In such case, the protection layer 28 only covers parts of the outside surfaces of the light pervious house 21. For example, one of a top surface 2120 of a top plate 212 and the bottom surface 2140 of the bottom plate 214 can be exposed to sunlight. In the illustrated embodiment, the sunlight can pass through the top plate 212 to enter a light guide element 22 positioned in the light pervious house 21.

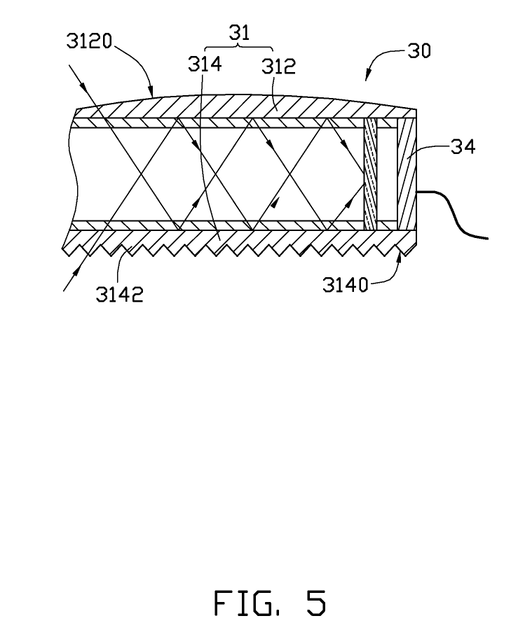

Referring to FIG. 5, a portable solar power generator 30 provided in a third exemplary embodiment is similar to the portable solar power generator 10 of the first embodiment. However, in the portable solar power generator 30, a top surface 3120 of a top plate 312 of a light pervious housing 31 is a curved surface, and a plurality of protrusions 3142 are formed on a bottom surface 3140 of a bottom plate 314 of the light pervious housing 31. In the illustrated embodiment, the curvature of the top surface 3120 is convex, and the protrusions 3142 of bottom surface 3140 are in the form of triangular prisms. Thus, the top surface 3120 and the bottom surface 3140 have a larger surface area than would be the case if they were simply planar surfaces. Accordingly, more sunlight can enter the portable solar power generator 30, and a photoelectric conversion efficiency of a solar cell unit 34 of the portable solar power generator 30 is improved. It can be understood that, in further or alternative embodiments, one of the top surface 3120 and the bottom surface 3140 may be a curved surface with many protrusions formed thereon.

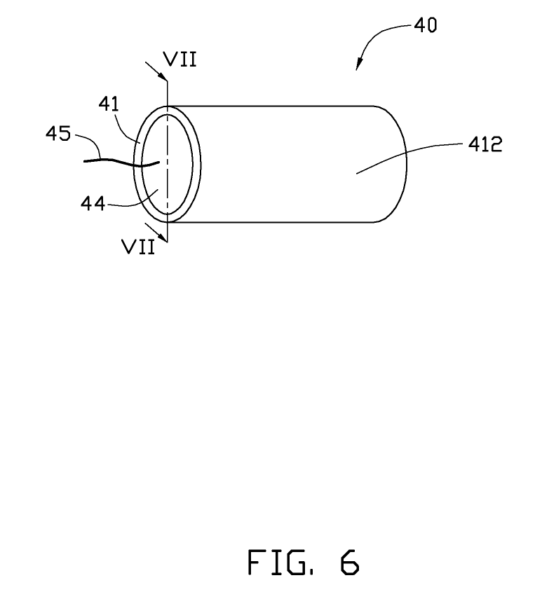

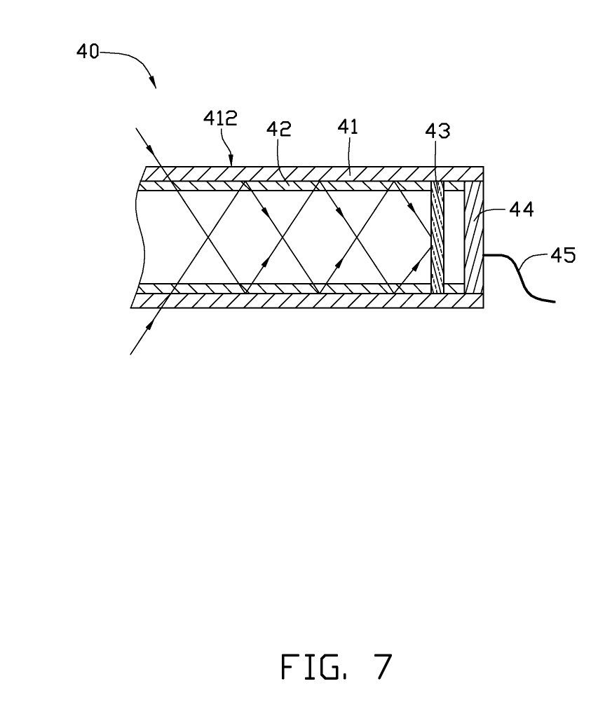

As illustrated in FIGS. 6 and 7, a portable solar power generator 40 provided in a fourth exemplary embodiment includes a light pervious housing 41, a light guide element 42, a condensing lens 43, a solar cell unit 44, and a connector assembly 45.

The light pervious housing 41 has a hollow cylindrical structure, and has a first refractive index. An outer surface 412 of the light pervious housing 41 serves as a light incident surface thereof. Sunlight can pass through the outer surface 412 and enter the light pervious housing 41.

The light guide element 42 is a cylindrical tube, and is positioned in the light pervious housing 41, being attached to an inner side of the light pervious housing 41. The light guide element 42 has a second refractive index, which is greater than the first refractive index of the light pervious housing 41.

The condensing lens 43 is positioned in the light pervious housing 41, near the solar cell unit 44. The condensing lens 43 may be positioned adjacent to the light guide element 42, or in the light guide element 42. In the illustrated embodiment, the condensing lens 43 is positioned in an end portion of the light guide element 42. In particular, an annular periphery of the condensing lens 13 is embedded in the end portion of the light guide element 42. The condensing lens 43 converges light incident thereon.

The solar cell unit 44 is positioned in the light pervious housing 41 adjacent to the light guide element 42, and near the condensing lens 43. That is, the solar cell unit 44 is located at a side of the condensing lens 43 opposite to the side where the majority of the light guide element 42 is located. The solar cell unit 44 is configured for receiving the light converged by the condensing lens 43 and converting the received light into electrical energy.

The connector assembly 45 is electrically coupled to the solar cell unit 44. A power consuming device (i.e., an energy storing means, not shown) can be connected to an outer end of the connector assembly 45. Thus, the electrical energy generated from the solar cell unit 44 can be transferred to the power consuming device by the connector assembly 45.

Due to the first refractive index being less than the second refractive index, sunlight can successfully enter the light guide element 42 by passing through the light pervious housing 41 and the light guide element 42. Such light within the light guide element 42 can then be trapped in the housing 41 by total internal reflection (TIR). Thereby, the sunlight received in the light guide element 42 can efficiently transmit to the condensing lens 43. The light introduced onto the condensing lens 43 can then be converged onto the solar cell unit 44, and the solar cell unit 44 can convert the received light into electrical energy. The electrical energy may be stored in the solar cell unit 44. The electrical energy generated from the solar cell unit 44 can be transferred to the power consuming device (not shown) by the connector assembly 45. In addition, because of the convergence of the light by the condensing lens 43, the light introduced onto the solar cell unit 44 is centralized. Accordingly, a photoelectric conversion efficiency of the solar cell unit 44 is improved.

While certain embodiments have been described and exemplified above, various other embodiments will be apparent to those skilled in the art from the foregoing disclosure. The present invention is not limited to the particular embodiments described and exemplified but is capable of considerable variation and modification without departure from the scope and spirit of the appended claims.

What is claimed is:

1. A portable solar power generator, comprising:
a hollow light pervious housing comprising an outer surface and having a first refractive index, wherein the light pervious housing is able to receive sunlight passing through at least part of the outer surface thereof;
a light guide element positioned in and attached to the hollow light pervious housing, the light guide element having a second refractive index larger than the first refractive index of the hollow light pervious housing;
a condensing lens positioned in the light pervious housing adjacent to or in the light guide element, wherein at least a majority of the light guide element is located at an input side of the condensing lens, the condensing lens configured for converging light incident on the input side thereof;
a solar cell unit positioned in the light pervious housing, and located at an opposite output side of the condensing lens, the solar cell unit configured for receiving the light converged by the condensing lens and converting the received light into electrical energy; and
a connector assembly electrically coupled to the solar cell unit for outputting the electrical energy of the solar cell unit from the portable solar power generator.

2. The portable solar power generator of claim 1, wherein the light pervious housing has a hollow plate-shaped structure, the light pervious housing comprises a top plate and a bottom plate, and the top plate has a top light incident surface and the bottom plate has a bottom light incident surface, the light guide element comprising a first reflecting plate and an opposite second reflecting plate, the first reflecting plate and the second reflecting plate being respectively in contact with the top plate and the bottom plate.

3. The portable solar power generator of claim 2, wherein two opposite ends of the condensing lens are embedded in the first and second reflecting plates respectively.

4. The portable solar power generator of claim 2, wherein at least one of the top light incident surface and the bottom light incident surface is a plane surface.

5. The portable solar power generator of claim 2, wherein at least one of the top light incident surface and the bottom light incident surface is a curved surface.

6. The portable solar power generator of claim 2, wherein the light pervious housing further comprises a plurality of protrusions formed on at least one of the top light incident surface and the bottom light incident surface.

7. The portable solar power generator of claim 6, wherein the protrusions are in the form of triangular prisms.

8. The portable solar power generator of claim 1, further comprising a protection layer covering at least part of the outer surface of the light pervious housing.

9. The portable solar power generator of claim 8, wherein the protection layer comprises light pervious material.

10. The portable solar power generator of claim 8, wherein the protection layer comprises opaque material, and the protection layer covers only part of the outside surface of the light pervious housing.

11. The portable solar power generator of claim 1, wherein the light pervious housing has a hollow cylindrical structure.

12. The portable solar power generator of claim 11, wherein the light guide element is a cylindrical tube positioned in the light pervious housing and attached to an inner side of the light pervious housing.

13. The portable solar power generator of claim 12, wherein an annular peripheral portion of the condensing lens is embedded in the light guide element.

14. A portable solar power generator, comprising:
a hollow shell body comprising an inner layer and an outer layer covering and attached to the inner layer, the outer layer and the inner layer respectively having a first refractive index and a second refractive index, the second refractive index being larger than the first refractive index, the hollow shell body capable of accepting sunlight passing through at least parts of the outer layer and the inner layer;
a condensing lens positioned in the hollow shell body and attached to the inner layer of the hollow shell body, wherein at least a majority of the inner layer is located at an input side of the condensing lens, the condensing lens configured for converging light incident on the input side thereof;
a solar cell unit positioned in the hollow shell body and located at an opposite output side of the condensing lens, the solar cell unit configured for receiving the light converged by the condensing lens and converting the received light into electrical energy; and
a connector assembly electrically coupled to the solar cell unit for outputting the electrical energy of the solar cell unit from the portable solar power generator.

15. The portable solar power generator of claim 14, wherein the hollow shell body has a hollow plate-shaped structure, the outer layer comprises a top portion and a bottom portion, and the top portion has a top light incident surface and the bottom portion has a bottom light incident surface, the inner layer comprising a first reflecting portion and an opposite second reflecting portion, the first reflecting portion and the second reflecting portion being respectively in contact with the top portion and the bottom portion.

16. The portable solar power generator of claim 15, wherein at least one of the top light incident surface and the bottom light incident surface is a plane surface.

17. The portable solar power generator of claim 15, wherein at least one of the top light incident surface and the bottom light incident surface is a curved surface.

18. The portable solar power generator of claim 15, wherein the outer layer further comprises a plurality of protrusions formed on at least one of the top light incident surface and the bottom light incident surface.

19. The portable solar power generator of claim 14, further comprising a protection layer covering at least part of the outer layer of the light pervious housing.

20. The portable solar power generator of claim 14, wherein the hollow shell body has a hollow cylindrical structure.
